(19) United States
(12) Patent Application Publication
(10) Pub. No.: US 2007/0294890 A1
(43) Pub. Date: Dec. 27, 2007

(54) PRINTED CIRCUIT BOARDS AND THE LIKE WITH IMPROVED SIGNAL INTEGRITY FOR DIFFERENTIAL SIGNAL PAIRS

(75) Inventors: Franz Gisin, San Jose, CA (US); Greg Schroeder, Morgan Hill, CA (US)

Correspondence Address: PERKINS COLE LLP, 101 JEFFERSON DRIVE, MENLO PARK, CA, 94025, US

(73) Assignee: Sanmina-SCI Corporation, San Jose, CA (US)

(21) Appl. No.: 11/770,581

(22) Filed: Jun. 28, 2007

Related U.S. Application Data
(62) Division of application No. 11/283,558, filed on Nov. 17, 2005.
(60) Provisional application No. 60/643,050, filed on Jan. 10, 2005.

(51) Int. Cl. H01K 3/10; H03H 7/38

(52) U.S. Cl. 29/852; 333/260

(57) ABSTRACT

A printed circuit board with improved signal integrity for one or more differential signal pairs incorporates one or more conductive regions. In an exemplary embodiment, via structures for the differential pair that interconnect signal traces are isolated from the conductive region by an antipad area around the via structures and a conductive bridge. In alternate embodiment, an antipad area around the via structures includes a bridge between the via structures. The antipad area may comprise, by way of non-limiting example, a clipped circular aperture or a modified rectangular aperture. The bridge may, by non-limiting examples, comprise a portion of the conductive region to permit impedance tailoring of the differential pair with respect to the conductive region.

### CROSS REFERENCE TO RELATED APPLICATION(S)

This divisional application claims the benefit of U.S. patent application Ser. No. 11/283,558, filed Nov. 17, 2005 and U.S. Provisional Application 60/643,050, filed Jan. 10, 2005, which are both herein incorporated by reference in their entirety.

### BACKGROUND

Exemplary embodiments disclosed herein pertain to electronic printed circuit boards which provide support and interconnectivity for electronic components to form electronic circuit apparatus. More particularly, exemplary embodiments disclosed herein pertain to printed circuit boards provided with differential signal pairs.

Today's electronic products, including computers, telecommunication equipment, and networking systems, are being designed to operate at ever increasing data transmission rates. Printed circuit boards, backplanes, midplanes, printed wiring boards, flex circuits, rigid flex-circuits, multi-chip modules (MCM), interposers and the like (herein referred to collectively as “PCBs”) have traditionally been considered as merely passive interconnects, but increasingly, PCBs are recognized to have potentially deleterious effects on integrity or fidelity of signals carried by the PCB.

One method for improving signal integrity in a PCB includes the use of differential signal pairs. Generally, two conductors of a differential signal pair are designed to run in the PCB close to each other, so that a source of electrical noise coupled to the differential pair represents “common mode noise” that is relatively easily minimized or eliminated. The separation distance between the conductors defining a differential pair influences the characteristic impedance of the differential pair.

A via structure typically provides a conductive path between conductive layers in the z-axis direction (i.e. orthogonal to the x-y plane of a PCB) Via holes are formed by a variety of techniques including but not limited to laser drilling, mechanical drilling, and techniques based on photo definition. They are subsequently partially or wholly filled or coated with a conductive material, usually metal. These via structures may be blind, buried, through-hole and may or may not include pads on the conductive layers, as is well known to those skilled in the art of PCB design.

PCB via structures used to route differential pair signals between conductive layers of a PCB can reduce the characteristic impedance of the PCB to an unacceptably low level. Within the PCB via structure, the size and shape of the pad (if present) and antipad impact the characteristic impedance of the differential pair as it is routed through the via structure.

One limitation of the prior art is the lack of impedance control with respect to differential pairs in that the pad (if present) and antipad shape are predominantly circular and size limited by the design considerations of the PCB. This, as noted above, may result in unacceptably low impedances.

U.S. Pat. No. 6,607,402, incorporated herein by reference, describes a configuration for increasing the characteristic impedance of a differential pair as it is routed through a set of PCB vias by removing conductive material between the two via structures used to route the differential pairs between conductive plane layers so that the antipad regions from the two via structures comprising the differential pair form one large antipad region.

One exemplary limitation of the prior art is a lack of a provision for impedance tailoring with respect to the differential pairs. This results in reduced system performance due to a lack of optimum impedance matching with the signals on the differential pairs.

These and other limitations of the prior art will become apparent to those of skill in the art upon a reading of the following descriptions and a study of the several figures of the drawing.

### SUMMARY OF EXEMPLARY EMBODIMENTS

In certain exemplary embodiments, a printed circuit board (PCB) with improved signal integrity for one or more differential signal pairs incorporates one or more conductive regions. Vias for a differential pair that interconnect two or more signal trace layers, in certain embodiments, are isolated from the conductive region by an “antipad” defined as a nonconductive area around the via structures. In some instances, an antipad area for the vias may include a conductive “bridge” between the via structures.

An embodiment, by way of non-limiting example, includes a first via structure configured as a first portion of a circuit for a differential pair, a second via structure configured as a second portion of the circuit for the differential pair, a first antipad area surrounding the first via structure isolating the first via structure from a conductive region on the same layer of the printed circuit board as the antipad, a second antipad area similar in shape and function to the first antipad area surrounding the second via structure, and a conductive bridge placed between the antipad regions associated with the first and second via structure. The ends of the conductive bridge may be connected to the conductive region that surrounds the entire set of via structures and antipads.

One advantage that the bridge provides is the ability to tailor the impedance of the differential pairs with respect to the conductive region, resulting in improved signal integrity and enhanced performance of the electronic circuit device.

These and other embodiments and advantages of the bridge and other features disclosed herein will become apparent to those of skill in the art upon a reading of the following descriptions and a study of the several figures of the drawing.

### BRIEF DESCRIPTION OF THE DRAWINGS

Several exemplary embodiments will now be described with reference to the drawings, wherein like components are provided with like reference numerals. The exemplary embodiments are intended to illustrate, but not to limit, the invention. The drawings include the following figures:

FIG. 1 illustrates a cross-sectional view of a multilayer PCB, in an exemplary embodiment;

FIG. 2 illustrates a portion of the conductive region of FIG. 1, showing further detail of exemplary antipad regions and a conductive bridge; and

FIG. 3 illustrates a portion of the conductive region 110c of FIG. 1, showing further detail on the exemplary antipad regions 130 and 131 and the conductive bridge 132 of an alternate exemplary embodiment.

### DETAILED DESCRIPTION OF EXEMPLARY EMBODIMENTS

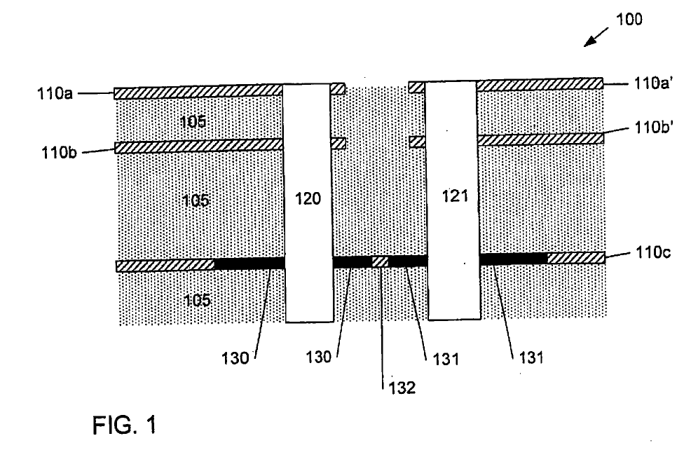

FIG. 1 is a cross-sectional view of a multilayer PCB 100 embodiment, in accordance with a non-limiting example. The PCB 100 includes a number of dielectric layers 105 separating a number of conductive layers 110. A differential signal pair includes a pair of signal traces 110a on the first layer, and a pair of signal traces 110b on the second layer. The differential pair comprises a positive going signal (e.g., carried by the signal traces 110a and 110b) and a negative going signal (e.g., carried by the signal traces 110a′ and 110b′). It will be appreciated that these signals can also be reversed. Furthermore, although depicted as being on adjacent layers, it will be appreciated that one or both of the signal traces 110a and 110b maybe formed on other layers of the PCB 100.

As used herein, a “conductive region” is part or all of a plane or layer of a PCB made from a conductive material such as copper. As used herein, a “via structure” includes, but is not limited to a via barrel formed within a via hole that extends between two or more layers of a PCB. A via structure may optionally include a via pad or the like. A “via barrel” refers to the conductive material within a via hole, which is often a hollow cylinder but which can be other shapes such as a solid cylinder, a partial cylinder, strips, and other shapes. A “via pad” is typically made from a conductive or partially conductive material which is in electrical contact with the via barrel. A “via antipad” is a nonconductive region surrounding or partially surrounding a via pad. An antipad may comprise an insulating material, or can simply be a void provided around the via.

As also used herein, a “conductive region” refers to either a partial or complete ground plane or a power plane. The conductive region may cover a complete layer or part of a layer. The conductive region therefore is typically fairly extensive, e.g., at least about 1 cm² or sometimes hundreds of centimeters square or larger as opposed to conductive traces which tend to be quite fine. That is, the area of the conductive region is greater than the area of conductive traces in the proximity of the vias.

A conductive via structure 120 couples one of the signal traces 110a of the differential pair to a respective signal trace 110b. A conductive via structure 121 couples the other of the signal traces 110a′ of the differential pair to the other respective signal trace 110b′. A first antipad region 130 is configured to isolate the via structure 120 from a conductive region 110c of the PCB 100. A second antipad region 131 is configured to isolate the via structure 121 from the conductive region 110c. A bridge 132 of the conductive region that normally surrounds the via structure 110c preferably separates the first antipad region 130 and the second antipad region 131.

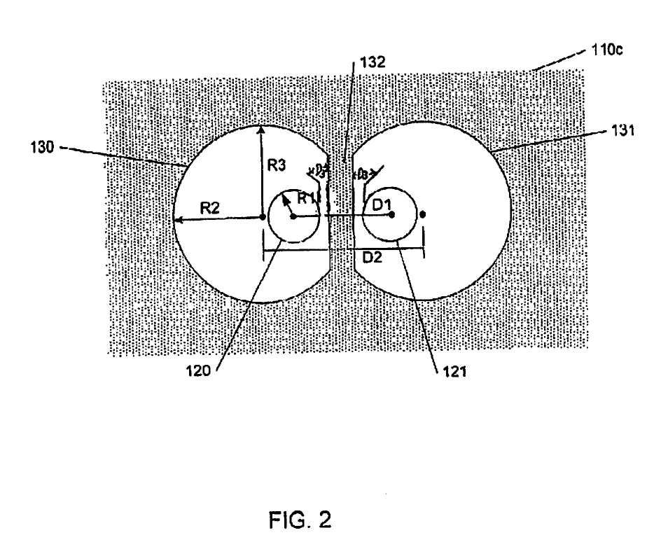

FIG. 2 illustrates a portion of the conductive region 110c of FIG. 1, showing further detail on exemplary antipad regions 130 and 131 and the bridge 132, in one embodiment in accordance with the present invention. In this embodiment, the via structure 120 and the via structure 121 are surrounded by the antipad regions 130 and 131 respectively. This isolates the via structure 120 and the via structure 121 from the conductive region 110c.

The via structure 120, in an exemplary embodiment, comprises a conductive via structure of radius R1, and similarly, the via structure 121 may comprise a conductive radius R1. The centers of the via structures 120 and 121, in this example, are separated by a distance D1. The antipad regions 130 and 131 comprise, for example, circular or elliptical geometries with radii R2 and R3, the centers of which are separated from each other by a distance D2. Other configurations comprise alternate embodiments.

By way of non limiting example and depending on connectors or other components to be coupled to the vias 120 and 121, R2 may be equal to, greater than, or less than R3; however, both R2 and R3 are larger than R1. D1 maybe equal to or less than D2. In an exemplary embodiment, D3 is less than R2 and R3.

In this example, antipad regions 130 and 131 represent clipped circular shaped nonconductive regions of, or apertures etched into, the conductive region 110c, with left-right symmetry about the center of the bridge 132, and with top-bottom symmetry about a line between centers of the pads for the vias 120 and 121. It will be appreciated that symmetry provides balanced impedances for the differential signals with the accompanying performance enhancement of the electronic device made with the PCB.

In some exemplary embodiments where D1=D2, the antipad regions 130 and 131 are such that a distance between the via structures 120 and 121 and the conductive region 110c is greater than a distance between the via structures 120 and 121 and the bridge 132. In one embodiment, the distance between the via structures 120 and 121 and the conductive region 110c is 0.008 inches, and the distance between the via structures 120 and 121 and the bridge 132 is 0.0055 inches. In this embodiment, the bridge 132 is 0.005 inches wide, formed by well known methods of etching the antipad into the conductive region 110c.

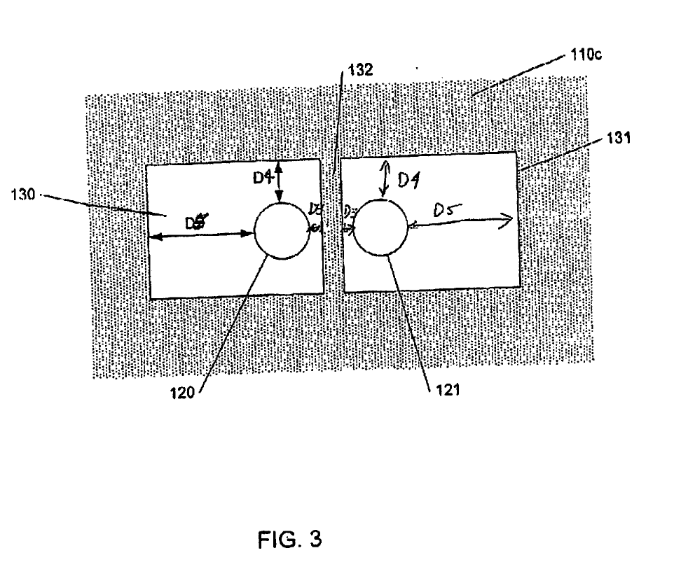

FIG. 3 illustrates the portion of the conductive region 110c of FIG. 1, showing further detail on the antipad regions 130 and 131 and the bridge 132, in another exemplary embodiment. In such embodiments, the antipad regions 130 and 131 comprise rectangular or modified rectangular shapes. Other shapes comprise additional embodiments. A distance D4 from the via structure 120 to the conductive region 110c may be greater than, equal to, or less than a distance D5 from the via structure 120 to the conductive region 110c. In this exemplary embodiment, D3 is less then D4 and D5. The antipad regions 130 and 131, in this example, are symmetrical left-to-right about the center of the bridge 132, and from top-to-bottom about a line between the pads for the vias 120 and 121. It will be appreciated that symmetry again advantageously provides balanced impedance for the differential signals. In an exemplary embodiment, D3 is less than D4 and D5.

In some embodiments, the antipad regions 130 and 131 comprise modified rectangular shapes with rounded corners. In some embodiments, the antipad regions 130 and 131 comprise modified rectangular shapes with 45 degree (i.e., mitered or beveled) corners. It will be appreciated that the modified rectangular shapes of these embodiments can improve processing (manufacturing) of the PCB, for example by improving reliability of etching of the conductive region 110c to form the antipad regions 130 and 131. Again, the suggested geometric shapes are by way of non limiting example, and various closed and open geometric shapes, including polygonal, curved, and compound shapes comprise various alternate embodiments.

In some embodiments, the bridge 132 represents a minimal line width of conductive material (e.g., copper) that still allows the pads of the vias 120 and 121 to be physically close to each other yet separate and isolated from each other. By way of non-limiting example, embodiments of the bridge width might be in the range of approximately 0.1 mils to approximately 5 mils. By way of additional non-limiting example, embodiments of the bridge the width might be in the range of about 2 mils to 4 mils. A particular non-limiting example of an embodiment would be, for example, 4 mils. In other non-limiting examples of alternate embodiments, the bridge width may be less than 0.1 mils or greater than 5 mils.

Determining preferred values for D1 through D5 can be accomplished using commonly available 3D numerical modeling and simulation tools including those based on FEM, FDTD, TLM, MOM. Those skilled in the use of these modeling and simulation tools can determine these dimensions utilizing standard modeling techniques.

In some embodiments, set forth by way of further non-limiting examples, the bridge 132 between the via structures 120 and 121 of the differential pair comprises a conductive material (e.g., 2 oz. copper) that is the same conductive material as the conductive region 110c. In alternative embodiments, the bridge 132 comprises a range of copper weight ranging from ¼ ounce to 4 ounces. In other embodiments, other materials than copper can be used, and other weights for the copper or other materials.

Although various embodiments have been described using specific terms and devices, such description is for illustrative purposes only. The words used are words of description rather than of limitation. It is to be understood that changes and variations may be made by those of ordinary skill in the art without departing from the spirit or the scope of the present invention, which is set forth in the following claims. In addition, it should be understood that aspects of various other embodiments may be interchanged either in whole or in part. It is therefore intended that the claims be interpreted in accordance with the true spirit and scope of the invention without limitation or estoppel.

1. A method for improving signal integrity for differential pairs comprising:
providing an energy plane;
providing a pair of antipads within the energy plane;
providing a pair of via structures within respective ones of the pair of antipads, where the pair of via structures are electrically coupled to a differential pair; and
providing a conductive bridge within the energy plane and separating the pair of antipads.

2. A method for improving signal integrity for differential pairs as recited in claim 1 wherein the antipads comprise an insulating material.

3. A method for improving signal integrity for differential pairs as recited in claim 1 further comprising forming the conductive bridge as a part of the energy plane.

4. A method for improving signal integrity for differential pairs as recited in claim 1 wherein the conductive bridge is made from a same conductive material as a conductive region of the energy plane.

5. A method for improving signal integrity for differential pairs as recited in claim 1 wherein the conductive bridge is a minimal line width of conductive material allowing the pair of antipads to be as physically close to each other as possible while still separate and isolated.

6. A method for improving signal integrity for differential pairs as recited in claim 1 further comprising connecting ends of the conductive bridge to the conductive region.

7. A method for improving signal integrity for differential pairs as recited in claim 1 further comprising etching apertures in the conductive region to form the antipads.

8. A method for improving signal integrity for differential pairs as recited in claim 1 further comprising:
forming via holes within the via structures by a technique selected from the group consisting of laser drilling, mechanical drilling, and photo definition;
forming via barrels within the via holes into a shape selected from the group consisting of a hollow cylinder, a solid cylinder, a partial cylinder, and strips, and wherein the via barrels are made from conductive material.

9. A method for improving signal integrity for differential pairs as recited in claim 1 further comprising reversing polarities of signal trace pairs.

10. A method for improving signal integrity for differential pairs as recited in claim 1 wherein a first conductive layer and a second conductive layer are parallel to the energy plane, perpendicular to the via structures, and separated by a plurality of layers.

11. A method for improving signal integrity for differential pairs as recited in claim 1 wherein the antipads are regions having a shape selected from the group consisting of circular-shaped regions, clipped circular-shaped regions, elliptical-shaped regions, rectangular shaped regions, modified rectangular-shaped regions, rectangular-shaped regions with rounded corners, rectangular-shaped regions with corners of about 45 degrees, closed geometric-shaped regions, open geometric-shaped regions, polygonal shaped regions, curved regions, and compound-shaped regions.

12. A method for improving signal integrity for differential pairs as recited in claim 1 wherein a first antipad of the pair of antipads is symmetrical about a longitudinal axis with a second antipad of the pair of antipads, and wherein the longitudinal axis is aligned with the center of the conductive bridge.

13. A method for improving signal integrity for differential pairs as recited in claim 1 wherein a first antipad of the pair of antipads is symmetrical about a latitudinal axis with a second antipad of the pair of antipads, and wherein the latitudinal axis is aligned with the center of the conductive bridge.

14. A method for improving signal integrity for differential pairs comprising:
providing a plurality of conductive layers and a plurality of dielectric layers;
providing a first conductive layer and a second conductive layer separated by a dielectric layer;
providing a positive going signal trace on the first conductive layer and negative going signal trace on the first conductive layer wherein the positive and negative signal traces form a first signal trace pair;
providing a positive going signal trace on the second conductive layer and a negative going signal trace on the second conductive layer wherein the positive and negative signal traces form a second signal trace pair;
coupling the first conductive layer to the second conductive layer using a via structure, including a first via and a second via;
providing non-conductive regions conterminous with at least a portion of the first via and at least a portion of the second via;
providing an at least partially conductive bridge, conterminous with the non-conductive regions between the first via and the second via.

15. The method of claim 14, further comprising adjusting the dimension of the non-conductive regions or the via structure, wherein adjusting the dimension tunes impedance associated with a differential pair.

16. A method comprising:
forming a differential pair on a partial or complete power plane;
coupling signal traces of the differential pair with via structures;
isolating the via structures from a conductive region with antipad regions;
separating antipad regions with a conductive bridge; and
tailoring an impedance of the differential pairs.

17. The method of claim 16, further comprising:
determining a distance D1 wherein D1 is a distance between centers of a first via structure and a second via structure;
determining a distance D2 wherein D2 is a distance between centers of a first antipad and a second antipad;
determining a distance D3 wherein D3 is a shortest distance from the first via structure to the second via structure; and
isolating the via structures from the conductive bridge on the power plane with distances D1, D2, and D3.

18. The method of claim 16, further comprising:
determining a distance D3 wherein D3 is the shortest from the first via structure to the second via structure;
determining a distance D4 wherein D4 is a distance from the center of the first via structure to an edge of the first antipad along a first axis parallel to the conductive bridge;
determining a distance D5 wherein D5 is a distance from the center of the first via structure to an edge of the first antipad along a second axis perpendicular to the conductive bridge;
isolating the via structures from the conductive bridge on the power plane with distances D3, D4, and D5.

19. The method of claim 16, further comprising using 3D numerical modeling and simulation tools to determine distances.

20. The method of claim 16, further comprising using techniques selected from the group consisting of FEM, FDTD, TLM, and MOM.
